(19) United States
(12) Patent Application Publication
(10) Pub. No.: US 2023/0343906 A1
(43) Pub. Date: Oct. 26, 2023

(54) LED PACKAGING DEVICE AND PREPARATION METHOD THEREFOR

(71) Applicant: QUANZHOU SANAN SEMICONDUCTOR TECHNOLOGY CO., LTD., Quanzhou (CN)

(72) Inventors: Shunyi CHEN, Xiamen (CN); Senpeng HUANG, Xiamen (CN); Dacheng LI, Quanzhou (CN); Junpeng SHI, Xiamen (CN); Changchin YU, Xiamen (CN); Chen-ke HSU, Xiamen (CN)

(21) Appl. No.: 18/347,670

(22) Filed: Jul. 6, 2023

Related U.S. Application Data
(63) Continuation of application No. PCT/CN2021/078822, filed on Mar. 3, 2021.

(51) Int. Cl. H01L 33/54

(52) U.S. Cl. CPC H01L 33/54

(57) ABSTRACT

An LED packaging device includes a packaging substrate, a LED chip and a packaging layer. The LED chip is disposed on a die-bonding area and between the packaging layer and the packaging substrate. The packaging layer (300) around the LED chip is configured with a stepped structure, and steps of which are defined as a first step, a second step, until an nth step sequentially in order from top to bottom. Each the step includes a step surface and a vertical surface, and a maximum horizontal distance between the vertical surface of the first step and the LED chip is less than a horizontal distance between the vertical surface of the nth step and the LED chip. The stepped structure reduces a thickness of the packaging layer around a side wall of the LED chip to reduce stress releasing of the packaging layer and increase reliability of the packaging device.

### TECHNICAL FIELD

The present disclosure relates to the field of light-emitting diode (LED) packaging technologies, particularly to a LED packaging device and a preparation method therefor.

### BACKGROUND

LEDs are widely used in various fields due to their reduced cost and improved efficiency. Existing LED packaging structures are mainly glass packaging structures, silicone packaging structures, or special resin film packaging structures. Considering a production cost and a feasibility of mass production, the special resin film packaging structures are currently the most advantageous LED packaging structures. However, the existing special resin film packaging structure will release stress in a long-term aging process, so that adhesion between a special resin film and a packaging substrate is poor, and thus it is easy to cause delamination between the special resin film and the packaging substrate, affecting reliability of the LED packaging structure.

### SUMMARY

A purpose of the present disclosure is to provide a LED packaging device, which can solve a problem of poor reliability of an existing LED packaging device resulting from a packaging layer is easy to fall off from the packaging substrate caused by poor adhesion between the packaging layer and the packaging substrate in the existing LED packaging device.

Another purpose of the present disclosure is to provide a preparation method for a LED packaging device.

In a first aspect, an embodiment of the present disclosure provides a LED packaging device, including:
a packaging substrate including a mounting surface, and the mounting surface being configured with a die-bonding area and a non-die-bonding area;
a LED chip, disposed on the die-bonding area of the packaging substrate; and
a packaging layer, disposed covering the die-bonding area and the non-die-bonding area of the packaging substrate. Moreover, the LED chip is located between the packaging layer and the packaging substate, the packaging layer around the LED chip is configured with a stepped structure, steps of the stepped structure are sequentially defined as a first step, a second step, until an nth step in an order from top to bottom, n is an integer greater than or equal to 2; each of the steps includes a step surface and a vertical surface, and a maximum horizontal distance between the vertical surface of the first step and the LED chip is less than a horizontal distance between the vertical surface of the nth step and the LED chip.

In the above embodiment, the packaging layer around the LED chip is configured with the stepped structure, so that a thickness of the packaging layer around a side wall of the LED chip is reduced, thereby reducing stress releasing of the packaging layer and improving reliability of the LED packaging device. Meanwhile, on the basis of ensuring the reliability of the LED packaging device, because the thickness of the packaging layer around the side wall of the LED chip is reduced, the packaging layer around the side wall of the LED chip can reduce absorption to light output from the LED chip, and thereby improve light output brightness of the LED chip.

In at least one embodiment, the stepped structure includes multiple steps, and the multiple steps are arranged along a height direction of the packaging substrate.

In the above implementation, a light output angle of the LED chip can be adjusted by changing the number of the steps to adjust the thickness of the packaging layer around the side wall of the LED chip.

In at least one embodiment, a roughness of the vertical surface is greater than 100 micrometers (μm).

In the above implementation, by configuring the vertical surface to be a rough surface with the roughness of greater than 100 μm, i.e., roughening the vertical surface, the light output brightness of the LED chip can be improved.

In at least one embodiment, a minimum vertical distance between the step surface of the first step and the LED chip is a first thickness, a minimum horizontal distance between the vertical surface of the first step and the LED chip is a second thickness, and a ratio of the first thickness to the second thickness is in a range of 1:5 to 3:1.

In at least one embodiment, a vertical distance between the step surface of the nth step and the mounting surface of the packaging substrate is a third thickness, and a ratio of the first thickness to the third thickness is in a range of 1:4 to 3:1.

In at least one embodiment, a ratio of the second thickness to the third thickness is in a range of 1:4 to 5:1.

In at least one embodiment, when a thickness of the LED chip is in a range of 200 μm to 400 the ratio of the first thickness to the second thickness is in a range of 1:5 to 2:1, the ratio of the first thickness to the third thickness is in a range of 1:2 to 2:1, and the ratio of the second thickness to the third thickness is in a range of 1:2 to 5:1.

In at least one embodiment, when a thickness of the LED chip is in a range of 400 μm to 700 the ratio of the first thickness to the second thickness is in the range of 1:5 to 3:1, the ratio of the first thickness to the third thickness is in the range of 1:4 to 3:1, and the ratio of the second thickness to the third thickness is in the range of 1:4 to 5:1.

In at least one embodiment, angles between the vertical surface of each of all the steps except for the nth step and the step surfaces adjacent thereto are in a range of 90° to 120°.

In at least one embodiment, the angles between the vertical surface of each of all the steps except for the nth step and the step surfaces adjacent thereto are 90°.

In at least one embodiment, the packaging substrate is configured (i.e., structured and arranged) with a recessed area surrounding the LED chip.

In some embodiments, the recessed area is discontinuously distributed along a circumferential direction of the LED chip, or the recessed area is continuously distributed along a circumferential direction of the LED chip.

In at least one embodiment, the LED chip is configured to emit light with a wavelength of less than 400 nanometers (nm).

In at least one embodiment, a material of the packaging layer includes a fluorine-containing material.

In a second aspect, an embodiment of the present disclosure provides a preparation method for the LED packaging device according to any one of the above embodiments of the present disclosure, and the preparation method includes:
securing a LED chip on a packaging substrate;
forming a packaging layer on a surface of the LED chip facing away from the packaging substrate, a side wall of the LED chip, and a region on the packaging substate in which the LED is not located; and
pre-cutting the packaging layer around the LED chip to form the stepped structure.

In a third aspect, an embodiment of the present disclosure provides a preparation method for the LED packaging device according to any one of the above embodiments of the present disclosure, and the preparation method includes:
securing multiple (i.e., more than one) LED chips on a packaging substrate;
forming a packaging layer on a surface of each of the multiple LED chips facing away from the packaging substrate, a side wall of each of the multiple LED chips, and a region on the packaging substrate in which the multiple LED chips are not located;
pre-cutting the packaging layer around each of the multiple LED chips to form stepped structures; and
cutting the stepped structure located between adjacent ones of the multiple LED chips to form LED packaging devices.

Compared with the related art, embodiments of the present disclosure may achieve beneficial effects as follows.

1) The packaging layer around the LED chip is configured with the stepped structure, so that a thickness of the packaging layer around a side wall of the LED chip is reduced, thereby reducing stress releasing of the packaging layer and improving reliability of the LED packaging device. Meanwhile, on the basis of ensuring the reliability of the LED packaging device, because the thickness of the packaging layer around the side wall of the LED chip is reduced, the packaging layer around the side wall of the LED chip can reduce absorption to light output from the LED chip, and thereby improve light output brightness of the LED chip.

2) The stepped structure includes multiple steps, and by way of changing the number of the steps to adjust the thickness of the packaging layer around the side wall of the LED chip, a light output angle of the LED chip can be adjusted consequently.

3) By configuring the vertical surface to be a rough surface with the roughness of greater than 100 μm, i.e., roughening the vertical surface, a light output brightness of the LED chip can be improved.

### BRIEF DESCRIPTION OF DRAWINGS

In order to more clearly illustrate technical solutions of embodiments of the present disclosure, drawings required in the embodiments will be briefly introduced below. It should be understood that the accompanying drawings merely illustrate some embodiments of the present disclosure, and therefore should not be regarded as limiting the scope of the present disclosure. For those of ordinary skill in the art, other relevant drawings can be obtained based on these drawings without creative effort.

FIG. 1 illustrates a schematic cross-sectional view of a LED packaging device according to an embodiment of the present disclosure.

FIG. 2 illustrates a schematic cross-sectional view of a LED packaging device according to another embodiment of the present disclosure.

FIG. 3 illustrates a schematic cross-sectional view of a LED packaging device according to still another embodiment of the present disclosure.

FIG. 4 illustrates a schematic cross-sectional view of a LED packaging device according to further another embodiment of the present disclosure.

FIG. 5 illustrates a schematic cross-sectional view of a LED packaging device according to even another embodiment of the present disclosure.

FIG. 6 illustrates a schematic cross-sectional view of a LED packaging device according to further still another embodiment of the present disclosure.

FIG. 7 illustrates a schematic cross-sectional view of a LED packaging device according to even still another embodiment of the present disclosure.

FIG. 8 illustrates a schematic flowchart of a preparation method for a LED packaging device according to an embodiment of the present disclosure.

FIGS. 9A-9C illustrate schematic cross-sectional views of a LED packaging device in different preparation processes according to an embodiment of the present disclosure.

Description of reference numerals in the accompanying drawings: 100, packaging substrate; 110, via; 200, metal layer; 210, die-bonding area; 220, non-die-bonding area; 230, isolation groove; 300, packaging layer; 400, stepped structure; 410, step surface; 420, vertical surface; 500, LED chip; 600, solder pad; 700, recessed area.

### DETAILED DESCRIPTION OF THE EMBODIMENTS

Embodiments of the present disclosure will be described below by way of specific examples, and other advantages and benefits of the present disclosure can be readily understood by those skilled in the art from contents disclosed in the specification. The present disclosure may be embodied and practiced by other different specific embodiments, and various details in the present disclosure may be modified and changed without departing from the spirit of the present disclosure based on different viewpoints and applications.

In the description of the present disclosure, it should be noted that orientations or positional relationships indicated by the terms “above”, “below”, “horizontal” and “vertical” are based on orientations or positional relationships shown in the accompanying drawings, or orientations and positional relationships commonly placed when products of the present disclosure are used, which are merely for the convenience of describing the present disclosure and simplifying the description, rather than indicating or implying that devices or elements referred to must have particular orientations, be constructed and operated in particular orientations, and therefore should not be construed as limiting the present disclosure. In addition, the terms “first”, “second” and the like are used for distinguishing descriptions merely, and are not to be construed as indicating or implying relative importance.

For the convenience of rear-end surface mounting, a LED chip with a thickness in a range of 200 to 700 μm needs to undergo a packaging process. In the packaging process of the LED chip, a fluorine-containing material is used for packaging the LED chip in a film pressing manner, and meanwhile ensures a top portion above a light-emitting surface of the LED chip to be flat. Since the fluorine-containing material needs to go through a high temperature process during a film pressing process, which easily causes the fluorine-containing material to release large thermal stress after the film pressing process, thereby causing delamination between the fluorine-contained material and a substrate, and more seriously, causing a metal pulling effect applied on the LED chip. Therefore, the present disclosure provides a novel LED packaging device, which can reduce a thickness of a packaging layer (fluorine-containing material) around a side wall of an LED chip to effectively reduce the release of thermal stress of the packaging layer, and moreover reduce absorption of the packaging layer around the side wall of the LED chip to light emitted from the LED chip, thereby improving overall brightness of the LED packaging device.

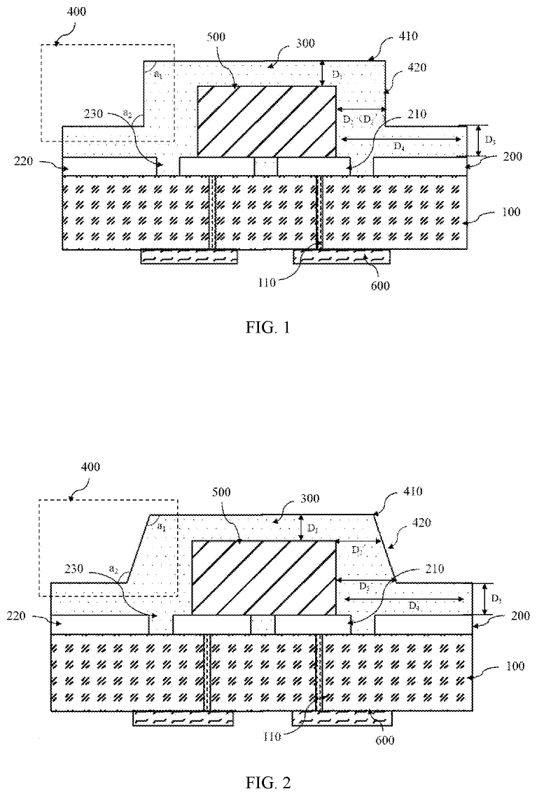

According to one aspect of the present disclosure, a LED packaging device is provided. As illustrated in FIG. 1 through FIG. 7, the LED packaging device includes a packaging substrate 100, a LED chip 500, and a packaging layer 300. The packaging substrate 100 includes a mounting surface, the mounting surface is configured with a die-bonding area 210 and a non-die-bonding area 220, and the mounting surface is an upper surface of the packaging substrate 100. The LED chip 500 is disposed on the die-bonding area 210 of the packaging substrate 100. The packaging layer 300 is arranged covering the die-bonding area 210 and the non-die-bonding area 220 of the packaging substrate 100, and the LED chip 500 is located between the packaging layer 300 and the packaging substrate 100. The packaging layer 300 around the LED chip 500 is configured with a stepped structure 400. Steps of the stepped structure 400, as per an order from top to bottom, are sequentially defined as: a first step, a second step, until an nth step, where n is a number of the steps of the stepped structure 400 and is generally an integer greater than or equal to 2. The first step is located at a side of the packaging layer 300 facing away from the packaging substrate 100, and the nth step is located at a side of the packaging layer 300 facing towards the packaging substrate 100. Each of the steps includes a step surface 410 and a vertical surface 420, a maximum horizontal distance between the vertical surface 420 of the first step and the LED chip 500 is less than a horizontal distance between the vertical surface 420 of the nth step and the LED chip 500.

In some embodiments, a wavelength of light emitted from the LED chip 500 is less than 400 nanometers (nm), and a material of the packaging layer 300 is a fluorine-containing material.

A working process and a working principle of the present disclosure are as follows.

In illustrated embodiments of the present disclosure, the packaging layer 300 around the LED chip 500 is configured with the stepped structure 400 to reduce the thickness of the packaging layer around the side wall of the LED chip 500, such that the release of stress of the packaging layer 300 is reduced and the reliability of the LED packaging device is improved. Meanwhile, on the basis of ensuring the reliability of the LED packaging device, since the thickness of the packaging layer 300 around the side wall of the LED chip 500 is reduced, the packaging layer 300 around the side wall of the LED chip 500 can reduce absorption to light emitted from the LED chip 500, such that light output brightness of the LED chip 500 is improved consequently.

Specific implementation structures of the LED packaging device will be described below.

### Embodiment 1

As illustrated in FIG. 1, the LED packaging device includes a packaging substate 100, a LED chip 500, and a packaging layer 300. A mounting surface of the packaging substrate 100 includes a metal layer 200 for forming a die-boding area 210 and a non-die-bonding area 220 outside the die-bonding area 210. The non-die-bonding area 220 and the die-bonding area 210 have an isolation groove 230 disposed therebetween, and the isolation groove 230 is used to electrically isolate the die-bonding area 210 from the non-die-bonding area 220. The LED chip 500 is disposed on the die-bonding area 210. The packaging layer 300 is arranged covering an upper surface and a side wall of the LED chip 500 and the metal layer 200. The packaging layer 300 around the LED chip 500 is configured with a stepped structure 400. A thickness of the metal layer is 50˜200 micrometers (μm), and in the illustrated embodiment, the thickness of the metal layer 200 is preferably 80 μm.

The stepped structure 400 includes two steps, and the two steps are arranged along a height direction of the packaging substrate 100 and sequentially defined as a first step and a second step according to an order from top to bottom. Each of the two steps includes a step surface 410 and a vertical surface 420, and a maximum horizontal distance D₂ between the vertical surface 420 of the first step and the LED chip 500 is less than a horizontal distance D₄ between the vertical surface 420 of the second step and the LED chip 500.

In an embodiment, the vertical surface 420 is a rough surface with a roughness of greater than 100 μm. By configuring the vertical surface 420 to be the rough surface, that is, roughening the vertical surface 420, light output brightness of the LED chip 500 can be improved. In this embodiment, compared to a non-roughened vertical surface 420, the roughened vertical surface 420 can improve the light output brightness by at least 5%.

Angles α₁, α₂ between the vertical surface 420 of the first step and the step surfaces 410 adjacent thereto each are in a range of 90°˜120°.

Preferably, as illustrated in FIG. 1, the angles α₁, α₂ between the vertical surface 420 of the first step and the step surfaces 410 adjacent thereto each are 90°, which can avoid a problem that the packaging layer 300 close to corners of the LED chip 500 is easy to crack, and thus improve reliability of the LED packaging device. As illustrated in FIG. 2, the angles α₁, α₂ between the vertical surface 420 of the first step and the step surfaces 410 adjacent thereto each are 120°.

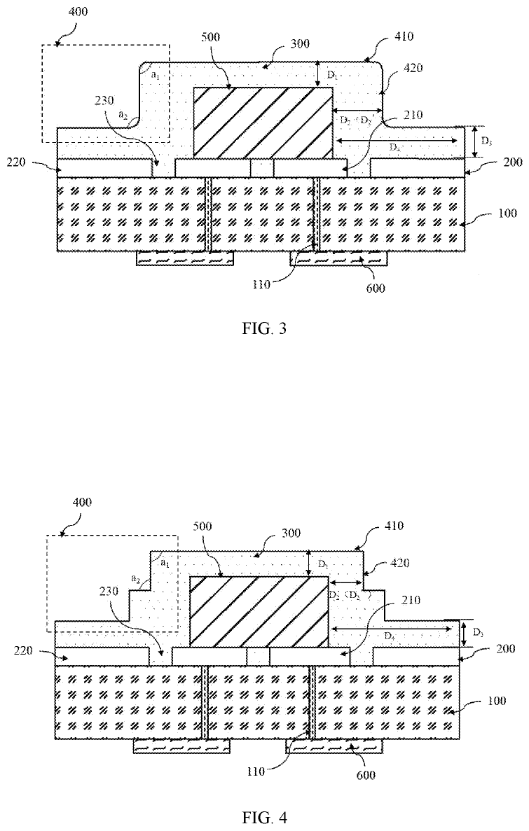

Preferably, as illustrated in FIG. 3, connection angles between the vertical surface 420 of the first step and the step surfaces 410 adjacent thereto each are an arc chamfer.

In an embodiment, as illustrated in FIG. 1, a minimum vertical distance between the step surface 410 of the first step and the LED chip 500 is a first thickness D₁. A minimum horizontal distance between the vertical surface 420 of the first step and the LED chip 500 is a second thickness D₂′, and the second thickness D₂′ is a thickness of the packaging layer around the side wall of the LED chip 500. A vertical distance between the step surface 410 of the second step and the mounting surface of the packaging substrate 100 (specifically refers to the mounting surface of the packaging substrate 100 including the metal layer 200) is a third thickness D₃, and the third thickness is D₃ is a thickness of the packaging layer 300 at the second step.

In a case that the thickness of the LED chip 500 is 200 μm˜700 μm, a ratio of the first thickness D₁ to the second thickness D₂′ is 1:5˜3:1, a ratio of the first thickness D₁ to the third thickness D₃ is 1:4˜3:1, and a ratio of the second thickness D₂′ to the third thickness D₃ is 1:4˜5:1. For example, the first thickness D₁ is 100 μm˜300 the second thickness D₂′ is 100˜500 μm, and the third thickness D₃ is 100˜400 μm.

Preferably, in a case that the thickness of the LED chip 500 is 200 μm˜400 μm, the ratio of the first thickness D₁ to the second thickness D₂′ is 1:5˜2:1, the ratio of the first thickness D₁ to the third thickness D₃ is 1:2˜2:1, and the ratio of the second thickness D₂′ to the third thickness D₃ is 1:2˜5:1. For example, the first thickness D₁ is 100 μm˜200 μm, the second thickness D₂′ is 100˜500 μm, and the third thickness D₃ is 100˜200 μm.

Preferably, in a case that the thickness of the LED chip 500 is 400 μm˜700 μm, the ratio of the first thickness D₁ to the second thickness D₂′ is 1:5˜3:1, the ratio of the first thickness D₁ to the third thickness D₃ is 1:4˜3:1, and the ratio of the second thickness D₂′ to the third thickness D₃ is 1:4˜5:1. For example, the first thickness D₁ is 100 μm˜300 μm, the second thickness D₂′ is 100˜500 μm, and the third thickness D₃ is 100˜400 μm.

Preferably, the first thickness D₁ is less than or equal to the second thickness D₂′, and by setting the first thickness D₁ and the second thickness D₂′ to have the above relationship, the packaging layer 300 on the upper surface of the LED chip 500 has a relatively small thickness, and the light output effect of the LED chip 500 is improved. Since the second thickness D₂′ is greater than the first thickness D₁, when the first thickness D₁ is small, the packaging layer 300 is prevented from cracking easily due to the reduced thickness of the packaging layer 300 close to the corners of the LED chip 500. Moreover, as seen from FIG. 1 through FIG. 3, an upper surface of the LED chip 500 is located between the step surface 410 of the first step and the step surface 410 of the second step, and thereby the step surface 410 of the second step is lower than the upper surface of the LED chip 500. In addition, as seen from FIG. 1 through FIG. 3, the vertical surface 420 of the first step is located between the side wall of the LED chip 500 and the vertical surface 420 of the second step (n=2), and the upper surface of the LED chip 500 is located between the step surface 410 (also referred to as horizontal step surface) of the first step and the step surface 410 of the nth step.

In an embodiment, the packaging substrate 100 includes a ceramic packaging substrate, a resin packaging substrate, an aluminum packaging substrate, or the like; and preferably, the packaging substrate 100 is the ceramic packaging substrate.

In an embodiment, as illustrated in FIG. 1, the die-bonding area 210 includes a first die-bonding region and a second die-bonding region separated from each other. The first die-bonding region is connected to a first electrically conductive layer of the LED chip 500, and the second die-bonding region is connected to a second electrically conductive layer of the LED chip 500. A polarity of the first die-bonding region is determined by a polarity of the first electrically conductive layer connected to the first die-bonding region, and a polarity of the second die-bonding region is determined by a polarity of a second electrically conductive layer connected to the second die-bonding region. A gap is left between the first die-bonding region and the second die-bonding region, and the gap and the isolation groove 230 are filled with the packaging layer 300.

In an embodiment, as illustrated in FIG. 1, a surface of the packaging substrate opposite to the mounting surface is disposed with solder pads 600, the packaging substrate 100 is formed with vias 110, and the solder pads 600 are electrically connected to the LED chip 500 through the vias 110. The solder pads 600 includes a first solder pad and a second solder pad, the first electrically conductive layer of the LED chip 500 is electrically connected to the first solder pad, and the second electrically conductive layer of the LED chip 500 is electrically connected to the second solder pad.

### Embodiment 2

This embodiment has many of the same features as the above embodiment 1, and differs from Embodiment 1 in that: the stepped structure 400 includes more than two steps. Herein, the same features will not be described below in detail, and only differences will be described.

As illustrated in FIG. 4, the stepped structure 400 includes more than two steps, and the more than two steps are sequentially defined as a first step, a second step, until an nth step according to an order from top to down. The stepped structure 400 with the more than two steps is suitable for a LED chip with a thickness of greater than 450 μm. Minimum horizontal distances between respective vertical surfaces 420 of the more than two steps and the LED chip 500 are gradually decreased in the height direction of the LED chip 500 from bottom to top, and the minimum horizontal distance between the vertical surface 420 of the first step and the LED chip 500 is the second thickness D₂′. Moreover, as seen from FIG. 4, an upper surface of the LED chip 500 is located between the step surface 410 of the first step and the step surface 410 of the second step, and thereby the step surface 410 of the second step is lower than the upper surface of the LED chip 500. In addition, as seen from FIG. 4, the vertical surface 420 of the first step is located between the side wall of the LED chip 500 and the vertical surface 420 of a third step (n=3), and the upper surface of the LED chip 500 is located between the step surface 410 (also referred to as horizontal step surface) of the first step and the step surface 410 of the third step.

Angles α₁, α₂ between the vertical surface of each of all the steps except the nth step and the step surfaces adjacent thereto each are in a range of 90°˜120°. Preferably, the angles α₁, α₂ between the vertical surface of each of all the steps except the nth step and the step surfaces adjacent thereto each are 90°; or, the angles α₁, α₂ between the vertical surface of each of all the steps except the nth step and the step surfaces adjacent thereto each are 120°.

In this embodiment, the thickness of the packaging layer 300 around the sidewall of the LED chip 500 is adjusted by adjusting the number of the steps in the stepped structure 400, such that a light output angle of the LED chip 500 is adjusted. For example, by increasing the number of the steps, the thickness of the packaging layer 300 around the side wall of the LED chip 500 is gradually decreased in the height direction of the LED chip 500 from bottom to top, such that the light output angle of the LED chip 500 is adjusted consequently.

### Embodiment 3

This embodiment has many of the same features as the above embodiment 1 or embodiment 2, and differences between this embodiment and the embodiment 1 or embodiment 2 are that: the packaging substrate 100 is configured with a recessed area 700, and the recessed area 700 surrounds the LED chip 500. Herein, the same features will not be described below in detail, and only the differences will be described.

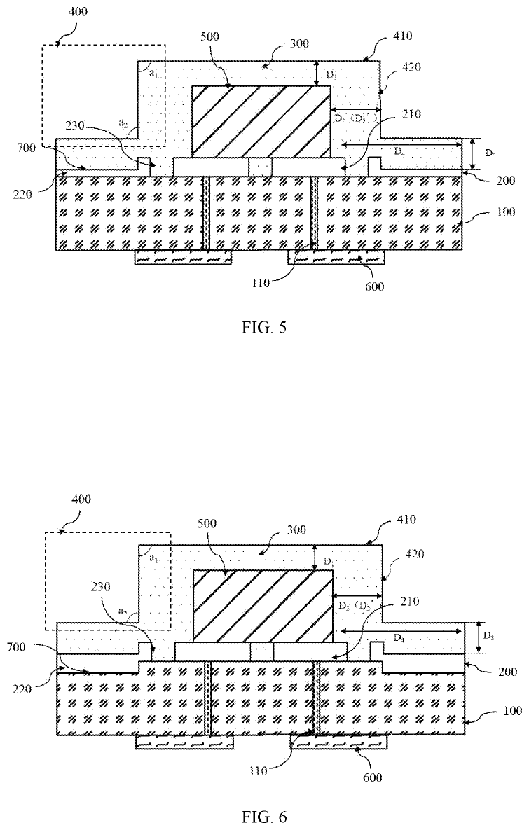

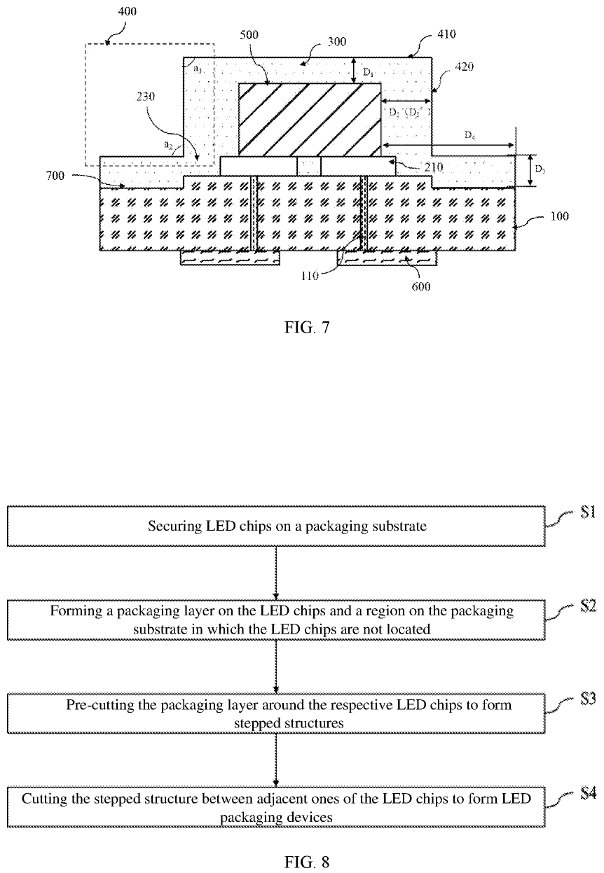

As illustrated in FIG. 5 through FIG. 7, the packaging substrate 100 is configured with the recessed area 700 surrounding the LED chip 500. More specifically, the recessed area 700 extends from an upper surface of the non-die-bonding area 220 of the mounting surface of the packaging substrate 100 to inside of the non-die-bonding area 220 (see FIG. 5); or, the recessed area 700 extends from an upper surface of the packaging substrate 100 to inside of the packaging substrate 100 (see FIG. 6); or, the mounting surface of the packaging substrate 100 does not include the non-die-bonding area 220, and the recessed area 700 may extend from the upper surface of the packaging substrate 100 to inside of the packaging substrate 100 (see FIG. 7). In addition, the recessed area 700 is discontinuously distributed along a circumferential direction of the LED chip 500; or, the recessed area 700 is continuously distributed along the circumferential direction of the LED chip 500.

Sum up, by configuring the recessed area 700 on the packaging substrate 100, the thickness of the packaging layer 300 around the side wall of the LED chip 500 can be further reduced. Moreover, the packaging layer 300 is connected with the packaging substrate 100 through the recessed area 700, which can increase a bonding force between the packaging layer 300 and the packaging substrate 100, reduce a path of external airflow entering the LED chip 500, and thereby improve the reliability of the LED packaging device. Moreover, as seen from FIG. 5 through FIG. 7, a surface of the packaging layer 300 located just below the step surface 410 of the nth step is lower than another surface of the packaging layer 300 in contact with an upper surface of the die-bonding area 210.

According to another aspect of the present disclosure, a preparation method for the LED packaging device as described in the above embodiments. As illustrated in FIG. 8, the preparation includes operations S1˜S4 as follows.

S1, securing multiple (i.e., more than one) LED chips 500 on a packaging substrate 100.

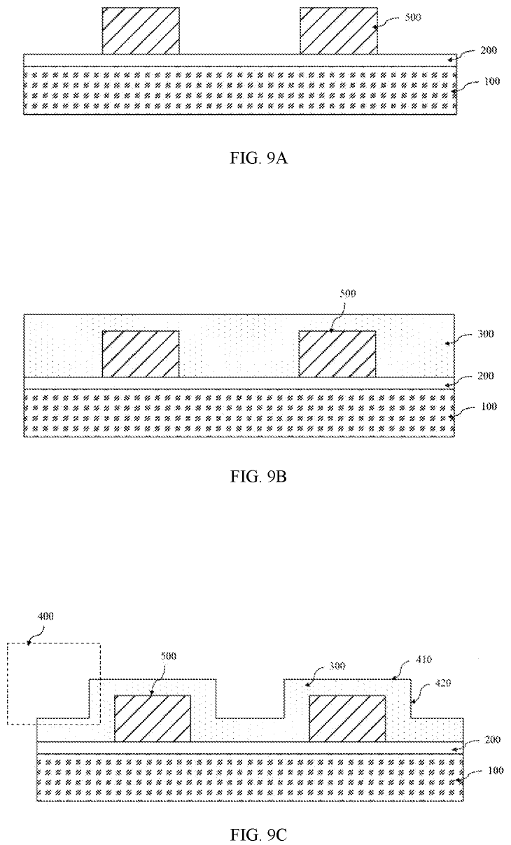

In an illustrated embodiment, as illustrated in FIG. 9A, the multiple LED chips 500 are arranged on the package substrate 100 at equal intervals. The packaging substrate 100 includes a ceramic packaging substrate, a resin packaging substrate, an aluminum packaging substrate, or the like; and preferably, the packaging substrate 100 is the ceramic packaging substrate.

Preferably, the packaging substrate 100 further includes a metal layer 200 for forming die-bonding areas 210, non-die-bonding areas 220 outside the respective die-bonding areas 210 and isolation grooves 230; and the multiple LED chips are disposed on the respective die-bonding areas 210.

Preferably, a wavelength of light emitted from each the LED chip 500 is less than 400 nm, and a thickness of each the LED chip 500 is in a range of 200 μm˜700 μm.

S2, forming a packaging layer 300 on a surface of each the LED chip 500 facing away from the packaging substrate 100, a side wall of each the LED chip 500, and a region on the packaging substrate 100 in which the multiple LED chips 500 are not located.

In an illustrated embodiment, as illustrated in FIG. 9B, the packaging layer 300 is formed on the surface of each the LED chip 500 facing away from the packaging substrate 100, the side wall of each the LED chip 500, and the region on the packaging substrate 100 in which the multiple LED chips 500 are not located, such that the packaging layer 300 packages each of the multiple LED chips 500. A material of the packaging layer 300 is a fluorine-containing material. A thickness of the packaging layer 300 above each the LED chip 500 is less than 200 μm, and a thickness of the packaging layer above the packaging substrate and between adjacent ones of the LED chips 500 is in a range of 300 μm˜500 μm.

The thickness of the packaging layer above the packaging substrate and between adjacent ones of the LED chips 500 can be adjusted according to the thickness of the LED chip 500. For example, when the thickness of the LED chip 500 is 250 μm, the thickness of the packaging layer above the packaging substrate and between adjacent ones of the LED chips 500 is 300 μm; or, when the thickness of the LED chip 500 is 430 μm the thickness of the packaging layer above the packaging substrate and between adjacent ones of the LED chips 500 is 500 μm.

S3, pre-cutting the packaging layer 300 around each of the LED chips 500 to form stepped structures 400.

In an illustrated embodiment, as illustrated in FIG. 9C, the packaging layer 300 around each of the LED chips 500 is pre-cut to form the stepped structure 400, and steps of the stepped structure 400 are sequentially defined as a first step, a second step, until an nth step according to an order from top to bottom. The stepped structure 400 surrounds the LED chip 500, which can reduce the thickness of the packaging layer 300 around the LED chip 500 and improve the light output brightness of the LED chip 500.

Preferably, a minimum vertical distance between a step surface 410 of the first step and the LED chip 500 is less than or equal to a minimum horizontal distance between a vertical surface 420 of the first step and the LED chip 500.

During the pre-cutting, the vertical surface 420 of each of the steps is configured as a rough surface, and a roughness of the rough surface is greater than 100 μm, which can increase the light output brightness of the LED chip by at least 5%.

In an illustrated embodiment, as illustrated in FIG. 9C, the stepped structure 400 includes multiple steps, and the multiple steps are arranged along a height direction of the packaging substrate 100. Each of the multiple steps includes one step surface 410 and one vertical surface 420, and a maximum horizontal distance between the vertical surface 420 of the first step and the LED chip 500 is less than a horizontal distance between the vertical surface 420 of the nth step and the LED chip 500. The thickness of the packaging layer 300 around the sidewall of the LED chip 500 is adjusted by adjusting the number of the steps in the stepped structure 400, such that the light output angle of the LED chip 500 is adjusted consequently.

S4, cutting the stepped structure 400 located between adjacent ones of the LED chips 500 to form LED packaging devices.

According to still another aspect of the present disclosure, a preparation method for the LED packaging device as described in above embodiments. The preparation method includes:
L1, securing a LED chip 500 on a packaging substrate 100, herein the number of the LED chip 500 is one;
L2, forming a packaging layer 300 on a surface of the LED chip 500 facing away from the packaging substrate 100, a side wall of the LED chip 500, and a region on the packaging substrate 100 in which the LED chip 500 is not located; and
L3, pre-cutting the packaging layer around the LED chip 500 to form a stepped structure 400.

As seen from the above technical solution, the packaging layer 300 around the LED chip 500 is configured as the stepped structure 400, which can reduce the thickness of the packaging layer 300 around the sidewall of the LED chip 500, thereby reducing the release of stress of the packaging layer 30 and improving the reliability of the LED packaging device. Meanwhile, on the basis of ensuring the reliability of the LED packaging device, because the thickness of the packaging layer 300 around the side wall of the LED chip 500 is reduced, the packaging layer 300 around the side wall of the LED chip 500 reduces the absorption to light emitted from the LED chip, and thus improves the light output brightness of the LED chips 500.

Further, the stepped structure 400 includes multiple steps, the thickness of the packaging layer 300 around the sidewall of the LED chip 500 can be adjusted by adjusting the number of the steps, and thereby the light output angle of the LED chip 500 can be adjusted consequently.

Further, the vertical surface 420 is configured to be a rough surface (also referred to as coarse surface) with a roughness of greater than 100 μm, i.e., the vertical surface 420 is roughened, which can improve the light output brightness of the LED chip 500.

The above description is merely preferred embodiments of the present disclosure, and it should be noted that, for those of ordinary skill in the art, several modifications and substitutions can be made without departing from the technical principles of the present disclosure, and these modifications and substitutions should also be considered as the scope of protection of the present disclosure.

What is claimed is:

1. A light-emitting diode (LED) packaging device, comprising:
a packaging substrate, comprising a mounting surface, wherein the mounting surface is configured with a die-bonding area and a non-die-bonding area;
a LED chip, disposed on the die-bonding area of the packaging substrate; and
a packaging layer, disposed covering the die-bonding area and the non-die-bonding area of the packaging substrate, wherein the LED chip is located between the packaging layer and the packaging substate, the packaging layer around the LED chip is configured with a stepped structure, steps of the stepped structure are sequentially defined as a first step, a second step, until an nth step in an order from top to bottom, n is an integer greater than or equal to 2; each of the steps comprises a step surface and a vertical surface, and a maximum horizontal distance between the vertical surface of the first step and the LED chip is less than a horizontal distance between the vertical surface of the nth step and the LED chip.

2. The LED packaging device according to claim 1, wherein the steps of the stepped structure are more than two steps, and the more than two steps are arranged along a height direction of the packaging substrate.

3. The LED packaging device according to claim 1, wherein a roughness of the vertical surface is greater than 100 micrometers (μm).

4. The LED packaging device according to claim 1, wherein a minimum vertical distance between the step surface of the first step and the LED chip is a first thickness, a minimum horizontal distance between the vertical surface of the first step and the LED chip is a second thickness, and a ratio of the first thickness to the second thickness is in a range of 1:5 to 3:1.

5. The LED packaging device according to claim 4, wherein a vertical distance between the step surface of the nth step and the mounting surface of the packaging substrate is a third thickness, and a ratio of the first thickness to the third thickness is in a range of 1:4 to 3:1.

6. The LED packaging device according to claim 5, wherein a ratio of the second thickness to the third thickness is in a range of 1:4 to 5:1.

7. The LED packaging device according to claim 6, wherein a thickness of the LED chip is in a range of 200 μm to 400 μm; and correspondingly the ratio of the first thickness to the second thickness is in a range of 1:5 to 2:1, the ratio of the first thickness to the third thickness is in a range of 1:2 to 2:1, and the ratio of the second thickness to the third thickness is in a range of 1:2 to 5:1.

8. The LED packaging device according to claim 6, wherein a thickness of the LED chip is in a range of 400 μm to 700 μm; and correspondingly the ratio of the first thickness to the second thickness is in the range of 1:5 to 3:1, the ratio of the first thickness to the third thickness is in the range of 1:4 to 3:1, and the ratio of the second thickness to the third thickness is in the range of 1:4 to 5:1.

9. The LED packaging device according to claim 1, wherein angles between the vertical surface of each of all the steps except for the nth step and the step surfaces adjacent thereto are in a range of 90° to 120°.

10. The LED packaging device according to claim 9, wherein the angles between the vertical surface of each of all the steps except for the nth step and the step surfaces adjacent thereto are 90°.

11. The LED packaging device according to claim 1, wherein the packaging substrate is configured with a recessed area surrounding the LED chip.

12. The LED packaging device according to claim 11, wherein the mounting surface comprises a metal layer of forming the die-bonding area and the non-die-bonding area outside the die-bonding area; and
the recessed area extends from an upper surface of the non-die-bonding area downwardly to inside of the non-die-bonding area, or the recessed area extends from an upper surface of packaging substrate in contact with the metal layer downwardly to inside of the packaging substrate and is located below the non-die-bonding area.

13. The LED packaging device according to claim 11, wherein the mounting surface comprises a metal layer of forming the die-bonding area, the recessed area extends from an upper surface of packaging substrate in contact with the metal layer downwardly to inside of the packaging substrate and is not covered by the metal layer.

14. The LED packaging device according to claim 11, wherein the recessed area is discontinuously distributed along a circumferential direction of the LED chip.

15. The LED packaging device according to claim 11, wherein the recessed area is continuously distributed along a circumferential direction of the LED chip.

16. The LED packaging device according to claim 1, wherein the LED chip is configured to emit light with a wavelength of less than 400 nanometers (nm).

17. The LED packaging device according to claim 1, wherein a material of the packaging layer comprises a fluorine-containing material.

18. The LED packaging device according to claim 1, wherein an upper surface of the LED chip facing away from the packaging substrate is located between the step surface of the first step and the step surface of the second step and thus the step surface of the second step is lower than the upper surface of the LED chip.

19. A LED packaging device, comprising:
a packaging substrate, disposed with a die-bonding area;
a LED chip, arranged on the die-bonding area; and
a fluorine-containing packaging layer, disposed covering the packaging substrate, the die-bonding area and the LED chip, wherein the LED chip is located between the fluorine-containing packaging layer and the packaging substrate;
wherein the fluorine-containing packaging layer around the LED chip is formed with a stepped structure, the stepped structure comprises steps arranged along a height direction of the LED chip, each of the steps comprises a horizontal step surface and a vertical surface, and the steps comprise a first step through an nth step sequentially arranged in an order from top to bottom, n is an integer greater than 2;
wherein the vertical surface of the first step is located between a sidewall of the LED chip and the vertical surface of the nth step, and an upper surface of the LED chip facing away from the packaging substrate is located between the horizontal step surface of the first step and the horizontal step surface of the nth step.

20. The LED packaging device according to claim 19, wherein a surface of the fluorine-containing packaging layer located just below the horizontal step surface of the nth step is lower than another surface of the fluorine-containing packaging layer in contact with an upper surface of the die-bonding area.
